(19) United States
(12) Patent Application Publication
(10) Pub. No.: US 2026/0101458 A1
(43) Pub. Date: Apr. 9, 2026

(54) DISPLAY DEVICE

(71) Applicant: LG ELECTRONICS INC., Seoul (KR)

(72) Inventors: Mikyung KIM, Seoul (KR); Youngjin CHOI, Seoul (KR); Jaejun LEE, Seoul (KR); Yohan CHOI, Seoul (KR)

(73) Assignee: LG ELECTRONICS INC., Seoul (KR)

(21) Appl. No.: 19/262,232

(22) Filed: Jul. 8, 2025

(30) Foreign Application Priority Data
Oct. 8, 2024 (WO) PCT/KR2024/015308

(51) Int. Cl. H05K 5/03; H05K 5/02; H05K 5/13

(52) U.S. Cl. CPC H05K 5/03; H05K 5/0221; H05K 5/0247; H05K 5/13

(57) ABSTRACT

Provided is a display device including a display module, a cover bottom coupled to a rear surface of the display module and including a first area and a second area on a rear surface thereof, a control module positioned on the first area of the cover bottom, a back cover covering the control module and fastened to the first area of the rear surface of the cover bottom, a fixing cover adjacent to the back cover and fastened to the second area of the rear surface of the cover bottom, and a stand assembly fastened to the fixing cover.

This application claims the benefit of International Application No. PCT/KR2024/015308, filed on Oct. 8, 2024, which is hereby incorporated by reference as if fully set forth herein.

### BACKGROUND

### Field

The present disclosure relates to a display device that may separate a back cover without separating a stand.

### Discussion of the Related Art

With growth of information society, demand for various display devices has increased. In order to satisfy such demand, in recent years, a liquid crystal display (LCD), a field emission display (FED), a plasma display panel (PDP), and an electroluminescent device have been developed as display devices.
A liquid crystal panel of the liquid crystal display includes a liquid crystal layer and a TFT substrate and a color filter substrate opposite each other in the state in which the liquid crystal layer is interposed therebetween, wherein a picture is displayed using light provided from a backlight unit.

Recently, because an element such as an OLED emits light by itself without a backlight structure on a rear surface, a flexible display module may be realized, thereby implementing a curved display device.

As a thickness of the display module becomes smaller, enlargement and weight reduction of the display device are in progress. As the display device becomes thinner and larger, there is a need for a small and light component.

As the size of the display device increases, it is difficult to secure enough space for mounting the display module to touch a floor surface for maintenance of the display device, and there is a risk of damage to the display module. Accordingly, there is a need for a method capable of replacing and repairing a control module mounted in the rear surface of the display device without laying the display device down.

### SUMMARY

The present disclosure is to provide a display device that may separate a back cover without separating a stand assembly.

Provided is a display device including a display module, a cover bottom coupled to a rear surface of the display module and including a first area and a second area on a rear surface thereof, a control module positioned on the first area of the cover bottom, a back cover covering the control module and fastened to the first area of the rear surface of the cover bottom, a fixing cover adjacent to the back cover and fastened to the second area of the rear surface of the cover bottom, and a stand assembly fastened to the fixing cover.

The fixing cover may be fastened to the cover bottom using a screw, and the back cover may be latch-coupled to the cover bottom and the fixing cover.

The back cover may include a first back cover and a second back cover respectively covering left and right sides of the first area, and at least a portion of the first back cover may overlap the second back cover.

The portion of the first back cover overlapping the second back cover may be screw-coupled to the cover bottom.

The first back cover may include a middle latch hole defined in the portion thereof overlapping the second back cover and a latch guide extending from the middle latch hole, and the second back cover may include a middle latch formed in a portion thereof overlapping the first back cover and inserted into the middle latch hole.

The fixing cover may be positioned between the first back cover and the second back cover.

The fixing cover may include a cable passing groove positioned in front of the stand and allowing a cable to pass therethrough.

The display device may further include a stand bracket positioned on a front surface of the fixing cover and fixed to the cover bottom, and the stand assembly may include a stand hook caught by the fixing cover, and a stand screw extending through the fixing cover and fastened to the stand bracket.

The display device may further include a module substrate positioned at a lower end of a rear surface of the display device and connected to the display module, the control module mounted on the first area of the cover bottom, and a flat cable passing through a space between the stand bracket and the cover bottom to connect the control module with the module substrate.

The display device may further include a lower casing top covering a lower portion of a front surface of the display module and a lower end of the display module, a bottom latch groove defined in the lower casing top, and a bottom latch formed at a lower edge of the back cover and inserted into the bottom latch groove.

The display device may further include a locking groove defined at an outer periphery of the cover bottom, and an edge protrusion formed at an edge of the back cover and inserted into the locking groove.

The display device of the present disclosure may separate the back cover without separating the stand assembly, thereby facilitating the maintenance of the product.

In addition, the display device of the present disclosure may provide the simple outer appearance structure via the fastening without the screw structure exposed to the outside.

In addition, the display device of the present disclosure may stably fasten the stand assembly.

Effects obtainable from the present disclosure may be non-limited by the above-mentioned effects. And, other unmentioned effects can be clearly understood from the following description by those having ordinary skill in the technical field to which the present disclosure pertains.

### BRIEF DESCRIPTION OF THE DRAWINGS

FIG. 1 is a front perspective view showing an example of the display device according to the present disclosure;

FIG. 2 is a rear perspective view showing an example of the display device according to the present disclosure;

FIG. 3 is a view illustrating a state in which a back cover of a display device of the present disclosure is separated.

FIG. 4 shows enlarged views of portions A and Bin FIG. 3.

FIG. 5 shows an enlarged view of a portion C in FIG. 3 and a cross-sectional view illustrating a fastened state of a connection latch.

FIG. 6 is a cross-sectional view taken along a line D-D in FIG. 2.

FIG. 7 is a cross-sectional view taken along a line E-E in FIG. 2.

FIG. 8 is a cross-sectional view taken along a line F-F in FIG. 2.

FIG. 9 is an exploded perspective view illustrating a coupling structure of a stand assembly of a display device according to the present disclosure.

FIGS. 10 and 11 are cross-sectional views illustrating a coupling structure of a stand assembly of a display device according to the present disclosure.

### DESCRIPTION OF SPECIFIC EMBODIMENTS

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

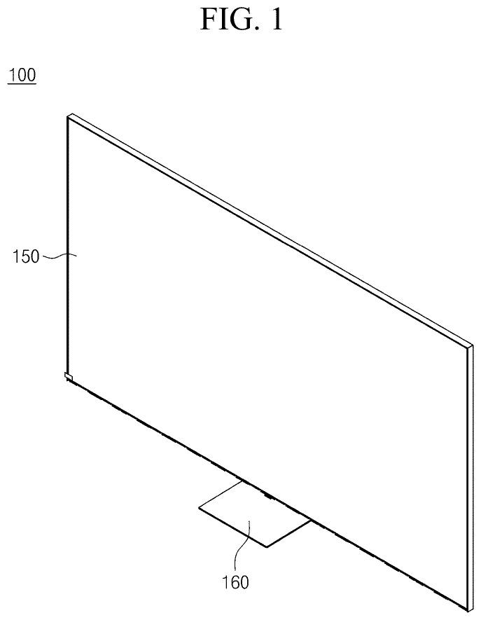

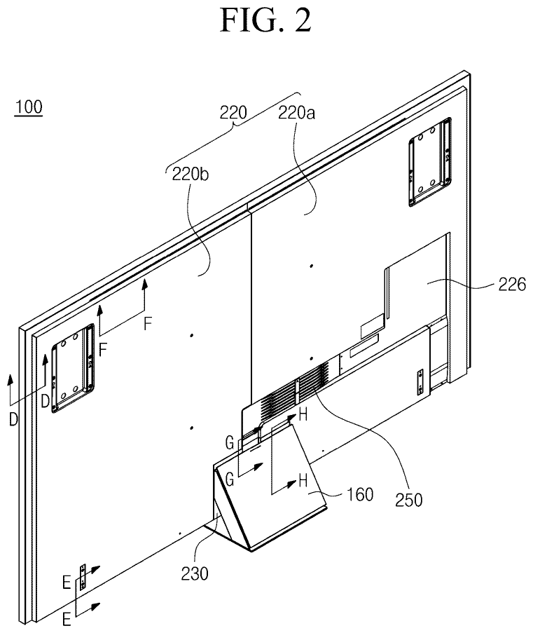

FIG. 1 is a front perspective view illustrating an example of a display device 100, and FIG. 2 is a rear perspective view. As an example of the display device 100, the display device 100 of a large screen having a small thickness is illustrated.

Recently, the display device 100 has been decreased in thickness but increased in size, so that a component thereof is required to have rigidity based on the great size of the device while having a small size. In line with such trend, each component tends to be thinner and miniaturized, but structural improvement thereof is required to ensure the rigidity.

Recently, in a display module 150, as a size of a non-display area located around a display area of a screen has decreased, a bezel has decreased, and a ratio of the screen to the size of the display device 100 has increased. A bezel-less design that seems to have almost no bezel is also being released, and an edge casing that covers a periphery of the display device and forms a side perimeter outer appearance is also able to be formed in a shape that covers only a lower portion without covering upper and left and right portions of a front surface.

The display module 150 may have a structure of a plurality of layers composed of a cover bottom 240 positioned on a rear surface thereof and a back cover 220 that forms a rear surface outer appearance of the device while covering various components including a main substrate coupled to a rear surface of the cover bottom 240.

To maintain and repair a control module 180 located on the rear surface of the cover bottom 240, it is necessary to separate the back cover 220 from the cover bottom 240. Accordingly, a coupling structure for fastening the back cover 220 to the cover bottom 240 requires a structure that enables the separation of the components while having a fixing force.

To separate the back cover 220 when inspecting the control module 180 of the display device 100, it is necessary to mount a front surface of the display device 100 facing the floor. Thereafter, a stand assembly 160 coupled to the back cover 220 may be separated from the back cover 220, and the back cover 220 may be separated from the cover bottom 240.

However, as the size of the display device 100 has increased recently, it is difficult to secure a space for seating the display device 100 on the floor indoors. In addition, there is a risk of damage when the front surface of the display module faces the floor surface.

To solve the above problem, the present disclosure provides a rear surface structure of the display device 100 capable of separating the back cover 220 without separating the stand assembly 160. The control module 180 on the rear surface of the cover bottom 240 may be replaced or repaired while the display device 100 of the present disclosure is standing in a vertical direction.

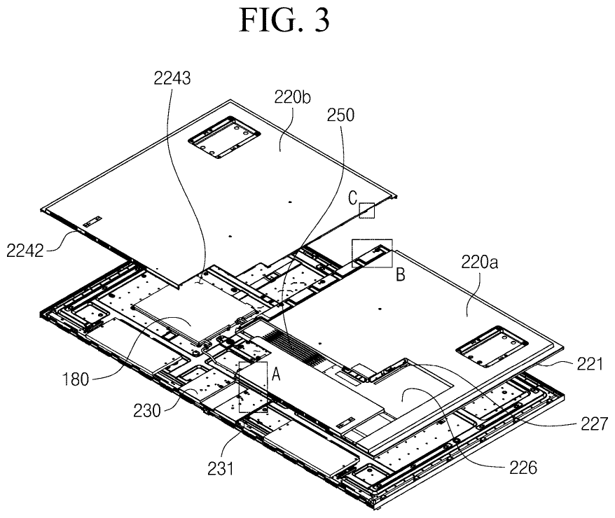

FIG. 3 is a view illustrating a state in which the back cover 220 of the display device 100 of the present disclosure is separated. A rear cover structure of the display device 100 of the present disclosure may be composed of the back cover 220 covering a first area in which the control module 180 is seated and a fixing cover 230 located in a second area to which the stand assembly 160 is fastened.

The fixing cover 230 may be fastened using a screw or the like to have a structure that has a strong fastening force and is not easily separated. The back cover 220 may use a locking structure that enables coupling and separation of components when a predetermined force is applied, such as a latch or a holder.

Although an embodiment in which only one stand assembly 160 is disposed at a center of the display device 100 is shown in FIGS. 2 and 3, a pair of stand assemblies 160 may be disposed to be spaced apart from each other in a left and right direction. In this case, a pair of fixing covers 230 may also be disposed to correspond to the number of stand assemblies 160.

Alternatively, in the case of the display device 100 supported by the pair of stand assemblies 160, after a temporary stand assembly 160 is fastened to the fixing cover 230, the existing stand assembly 160 may be separated to separate the back cover 220 while the display device 100 is standing.

The back cover 220 of the display device 100 of the present disclosure may be composed of two pieces as shown in FIG. 3 in consideration of case of manufacturing, transportation, and assembly. A first back cover 220a and a second back cover 220b may be arranged adjacent to each other in a left and right direction, and the fixing cover 230 may be positioned between the first back cover 220a and the second back cover 220b.

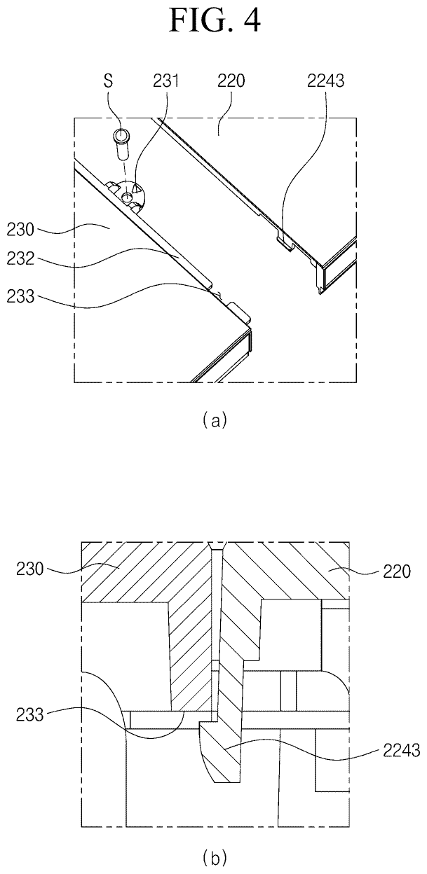

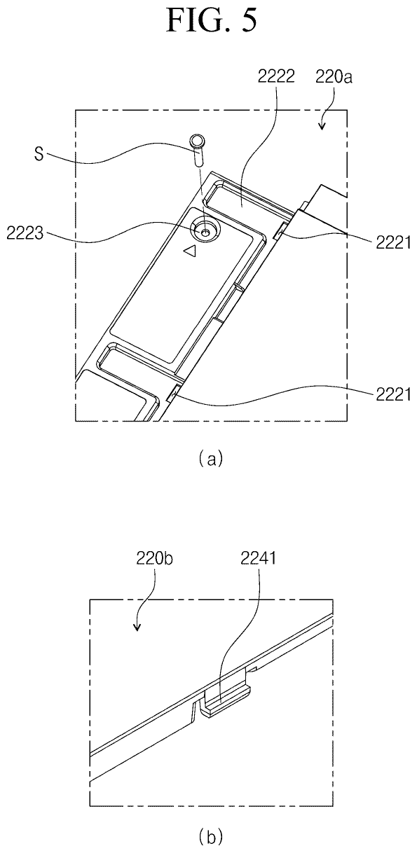

FIG. 4 shows an enlarged view of a portion A in FIG. 3 and a cross-sectional view illustrating a fastened state of a connection latch 2243, and FIG. 5 shows enlarged views of portions B and C in FIG. 3.

First, the fixing cover 230 is fastened to the cover bottom 240 using a screw S. Thereafter, the first back cover 220a may be fastened to the cover bottom 240, and the second back cover 220b may be fastened thereto. The fixing cover 230 is able to be fastened using the screw S for the fixing force of the stand assembly 160, and an embodiment in which the screws S are fastened to four places of the present disclosure is illustrated.

The first back cover 220a and the second back cover 220b may be coupled to the cover bottom 240 and the fixing cover 230 using latch structures 2241, 2242, and 2243 and a holder structure 223. Referring to (a) in FIG. 4, the back cover 220 may include a connection latch 2243 fastened to a latch locking portion 233 formed at an end of the fixing cover 230 fastened ahead.

The latch locking portion 233 may be disposed so as not to overlap a screw fastening portion 231 of the fixing cover 230. As shown in (a) in FIG. 4, an overlapping rib 232 may protrude from an edge area of the fixing cover 230 except for the latch locking portion 233 so as to overlap the back cover 220.

Referring to FIG. 5, an overlapping portion 222 of the first back cover 220a is illustrated. The first back cover 220a may include the overlapping portion 222 positioned in front of the second back cover 220b such that a connection portion between the first back cover 220a and the second back cover 220b is not opened and exposed.

As shown in (a) in FIG. 5, the second back cover 220b may be seated on a rear surface of the overlapping portion 222 of the first back cover 220a that is first coupled. A middle latch hole 2221 defined in the overlapping portion 222 of the first back cover 220a may be included, and as illustrated in (b) in FIG. 5, the second back cover 220b may include a middle latch 2241 inserted into an edge forming a boundary with the first back cover 220a.

The middle latch hole 2221 may be located at a boundary between the overlapping portion 222 and an exposed portion of the first back cover 220a, and may include a latch guide 2222 extending from an end of the overlapping portion 222 to the middle latch hole 2221 such that the middle latch 2241 is fastened to the middle latch hole 2221.

To prevent the first back cover 220b from being separated together when separating the second back cover 220a by releasing the middle latch 2241 fastened to the middle latch hole 2221, the overlapping portion 222 of the first back cover 220a may be fastened to the cover bottom 240 via the screw S.

Because a screw hole 2223 defined in the overlapping portion 222 of the first back cover 220a is covered by the second back cover 220b and is not exposed to the outside, the screw is not exposed to the outside of the display device 100 even when the fastening is achieved using the screw.

Locations of the first back cover 220a and the second back cover 220b may be interchanged. However, because it is easier to separate the second back cover 220b than the first back cover 220a coupled first, the control module 180 positioned in front of the first back cover 220a may have a component having a lower risk of failure than the control module 180 positioned in front of the second back cover 220b.

The first back cover 220a may include a terminal hole 227 through which a connection terminal is exposed. A connection cable for connection with an external device may be fastened to the connection terminal exposed through the terminal hole.

In addition, the first back cover 220a may include a cable accommodation module 250 for placing the connection cable. To prevent occurrence of a gap between the rear surface of the display device 100 and a wall caused by the connection cable located in the cable accommodation module 250, a cable recess 226 recessed forward in the rear surface of the first back cover 220a may be included.

When the connection cable is disposed in the cable accommodation module 250, because a load may be applied to the first back cover 220a because of a weight of the connection cable, a fastening force may be increased using the screw.

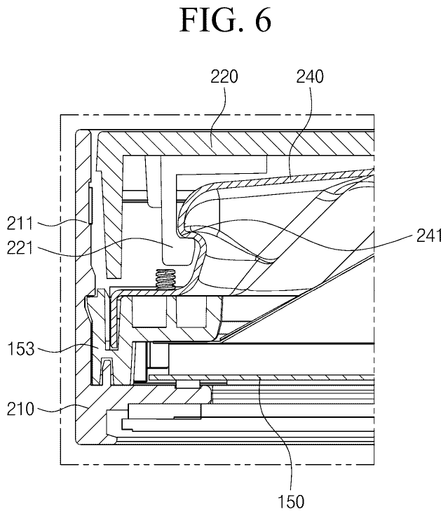

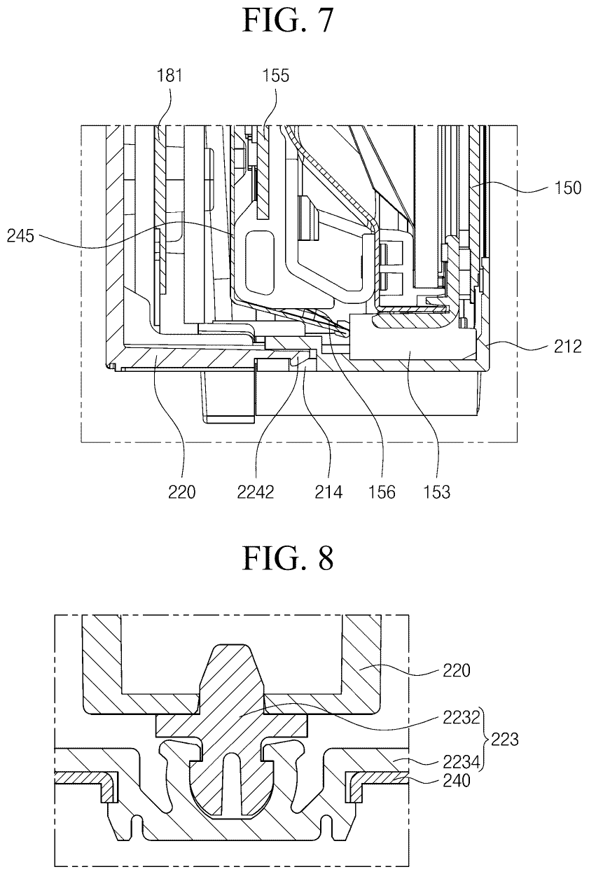

FIG. 6 is a cross-sectional view taken along a line D-D in FIG. 2, and FIG. 7 is a cross-sectional view taken along a line E-E in FIG. 2. FIG. 6 illustrates an edge portion at each of left and right sides of the display device 100. The back cover 220 may include an edge protrusion 221 inserted into a locking groove 241 defined at an edge of the cover bottom 240.

After the edge protrusion 221 of a lateral end of the first back cover 220a is inserted into the cover bottom 240, the overlapping portion 222 may be fastened with the screw S, and the connection latch 2243 may be fastened to the latch locking portion 233 of the fixing cover 230. After an edge protrusion of a lateral end of the second back cover 220b is inserted into the cover bottom 240, the middle latch 2241 may be inserted into the latch groove, and the connection latch 2243 may be fastened to the latch locking portion 233 of the fixing cover 230.

An edge casing 211 surrounding an outer periphery of the display device 100 is also referred to as a casing top and includes a structure exposed to the outside of the display device 100.

Because a side of the display device 100 may be exposed to the outside, the back cover 220 may be located inward of the edge casing 211 to construct the side surface of the display device 100 as one continuous member. The edge casing 211 may not be directly fastened to the back cover 220, and the edge casing 211 may be indirectly coupled thereto by being fastened with a guide panel 153 of the display module 150.

As illustrated in FIG. 7, a lower edge casing 212 constituting a lower portion of the display device 100 may cover a portion of the front surface of the display device 100, unlike the side surface. A lower end of the display module 150 requires a space through which a flexible substrate 156 for connection with a panel substrate 155 located on a rear surface of the module passes, so that even when the bezel-less design is implemented in the side or upper portion, the lower end needs to be partially covered.

The lower edge casing 212 may include a front portion positioned on the front surface of the display device 100 and a lower portion positioned at a lower portion. Because a load may be applied to the lower portion of the display device 100 in a direction of gravity when the device is mounted, a gap may occur between the back cover 220 and the edge casing 211, and thus, a latch structure may be equipped. A bottom latch 2242 formed at a lower portion of the back cover 220 may be included so as to be inserted into a bottom latch hole 214 defined in the edge casing 211.

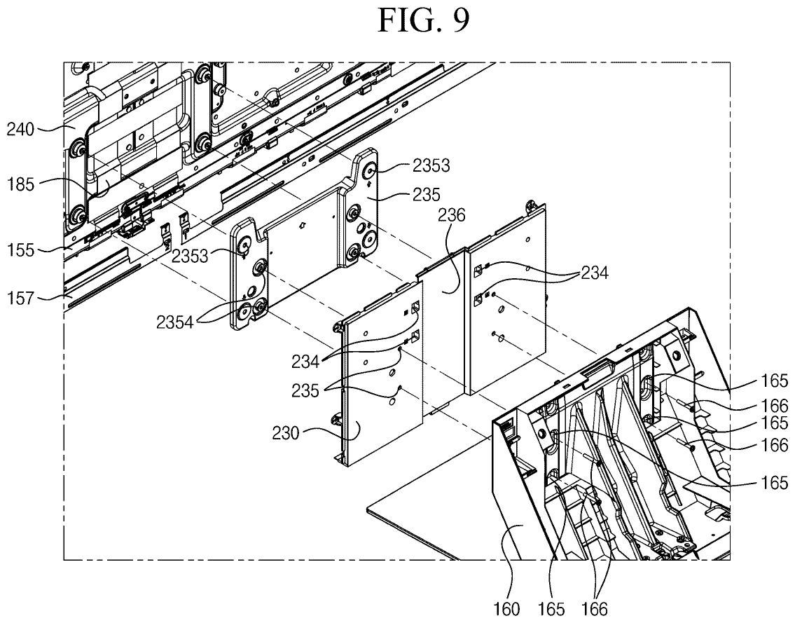

FIG. 8 is a cross-sectional view taken along a line F-F in FIG. 2. As the size of the display device 100 increases, it is difficult to secure the fixing force only with the latch structures 2241, 2242, and 2243 located at the edges of the back cover 220, so that a holder module 223 located in the middle of the back cover 220 may be included.

The holder module 223 may be composed of a first holder 2234 positioned on the rear surface of the cover bottom 240 and a second holder 2232 positioned on the front surface of the back cover 220, and may be coupled or separated by applying a force of a predetermined magnitude or greater using an elastic material. The holder module 223 may be disposed to be spaced apart from the latches 2241, 2242, and 2243 to stably fix a portion of the back cover 220 having insufficient fastening force.

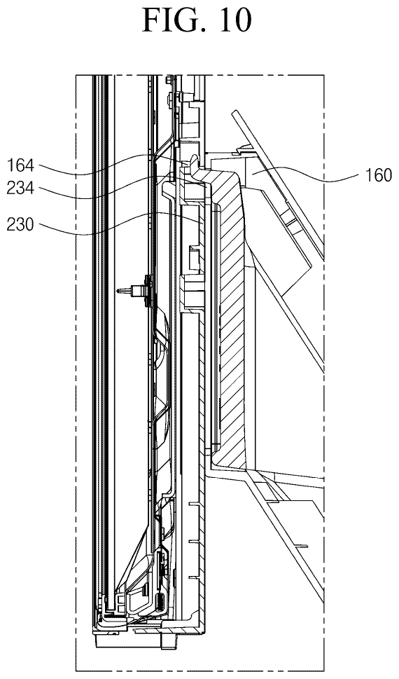

FIG. 9 is an exploded perspective view illustrating a coupling structure of the stand assembly 160 of the display device 100 according to the present disclosure. A hook hole and a screw hole 165 fastened to the stand assembly 160 may be included in a rear surface of the fixing cover 230.

The stand assembly 160 may include an internal space through which the connection cable connected to the display device 100 passes. The connection cable is disposed in the cable recess 226 defined in the first back cover 220a, and should pass through the fixing cover 230 to extend into the internal space of the stand. The fixing cover 230 may include a cable recess 236 connected to the cable recess 226. The cable recess 236 of the fixing cover 230 may be defined to overlap the stand assembly 160.

The fixing cover 230 may be made of the same material for a sense of unity with the back cover 220, and may be generally formed as an injection product. In this regard, when the stand assembly 160 is fastened only to the fixing cover 230, the rigidity may be weak and thus the fixing cover 230 may be damaged. In addition, the cover bottom 240 may also be constructed to be thin to reduce the thickness of the display device 100, so that it may be insufficient to support a total weight of the display device 100.

A stand bracket 235 having rigidity may be disposed between the fixing cover 230 and the cover bottom 240 for a stable fixing force of the stand assembly 160. The stand bracket 235 may include a first fastening portion 2353 fastened to the cover bottom and a second fastening portion 2354 fastened to the stand assembly 160.

The panel substrate 155 connected to the end of the display module 150 may be located at a lower portion of the rear surface of the cover bottom 240 of the display device 100 and may be connected to a flexible substrate or flat cable 185 to transmit and receive signals to and from the control module 180 located at the upper portion of the cover bottom 240.

The flat cable 185 may have a bilaterally symmetrical structure for synchronizing with the panel substrate 155 generally positioned lateral thereto, and may extend from a center upward as shown in FIG. 9.

In this regard, the flat cable 185 may be disposed to overlap the stand bracket 235 and pass through a space between the stand bracket 235 and the cover bottom 240. In addition to the effect of enhancing the fixing force of the stand assembly 160, the stand bracket 235 may provide the spaces in which the fastening portion for the stand assembly 160 and the flat cable 185 are placed overlapping at the center in a divided manner.

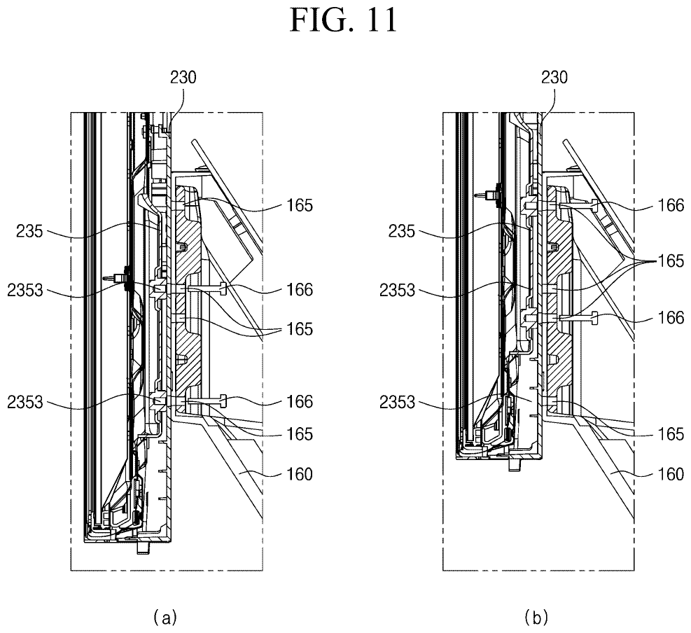

FIGS. 10 and 11 are cross-sectional views illustrating a coupling structure of the stand assembly 160 of the display device 100 of the present disclosure. FIG. 10 is a cross-sectional view taken along a line G-G in FIG. 2, and FIG. 11 is a cross-sectional view taken along a line H-H in FIG. 2.

As illustrated in FIG. 10, the stand assembly 160 may include a stand hook 164 inserted into the hook hole 234 of the fixing cover 230. In addition, as shown in (a) in FIG. 11, a stand screw 166 that extends through the screw hole 165 defined in the fixing cover 230 and is fastened to the stand bracket 235 may be included.

The stand hook 164 may include a pair of stand hooks arranged in the left and right direction for balance, and the stand screw 166 may include four stand screws to form a square for the fixing force. The stand screw 166 may be positioned lower than the stand hook 164.

As shown in FIG. 9, the hook hole 234 of the present disclosure may include a plurality of hook holes. A pair of hook holes 234 arranged in the left and right direction may be fastened to the pair of stand hooks 164 of the stand assembly 160.

The hook holes 234 arranged in the vertical direction have a structure for implementing two heights of the display device 100. When the stand hook 164 is fastened to a hook hole 234 located at an upper side, a vertical level of the display module 150 may be decreased, and when the stand hook 164 is fastened to a hook hole 234 located at a lower side, the vertical level of the display module 150 may be increased.

The number of screw holes 235 defined in the fixing cover 230 of the display device 100 of the present disclosure is four, but the number of screw holes 165 defined in the stand assembly 160 may be greater than the number of screw holes 235 defined in the fixing cover 230.

The stand screw 166 may be fastened to a different screw hole 165 of the stand assembly 160 depending on a vertical level of the hook hole 234 into which the stand screw 166 is inserted, thereby differently adjusting the mounting vertical level of the display module 150.

(a) in FIG. 11 illustrates the state in which the stand screw 166 is fastened to the screw hole 165b located at the lower side to lower the vertical level of the display module 150. (b) in FIG. 11 illustrates a state in which the stand screw 166 is fastened to the screw hole 165a located at the upper side to increase the vertical level of the display module 150.

As described above, the display device 100 of the present disclosure may separate the back cover 220 without separating the stand assembly 160, thereby facilitating the maintenance of the product.

In addition, the display device 100 of the present disclosure may provide the simple outer appearance structure via the fastening without the screw structure exposed to the outside.

In addition, the display device 100 of the present disclosure may stably fasten the stand assembly 160.

The above detailed description should not be construed as being limitative in all terms, but should be considered as being illustrative. The scope of the present invention should be determined by reasonable analysis of the accompanying claims, and all changes in the equivalent range of the present invention are included in the scope of the present invention.

What is claimed is:

1. A display device comprising:
a display module;
a cover bottom coupled to a rear surface of the display module and including a first area and a second area on a rear surface thereof;
a control module positioned on the first area of the cover bottom;
a back cover covering the control module and fastened to the first area of the rear surface of the cover bottom;
a fixing cover adjacent to the back cover and fastened to the second area of the rear surface of the cover bottom; and
a stand assembly fastened to the fixing cover.

2. The display device of claim 1, wherein the fixing cover is fastened to the cover bottom using a screw,
wherein the back cover is latch-coupled to the cover bottom and the fixing cover.

3. The display device of claim 1, wherein the back cover includes a first back cover and a second back cover respectively covering left and right sides of the first area,
wherein at least a portion of the first back cover overlaps the second back cover.

4. The display device of claim 3, wherein the portion of the first back cover overlapping the second back cover is screw-coupled to the cover bottom.

5. The display device of claim 3, wherein the first back cover includes a middle latch hole defined in the portion thereof overlapping the second back cover and a latch guide extending from the middle latch hole,
wherein the second back cover includes a middle latch formed in a portion thereof overlapping the first back cover and inserted into the middle latch hole.

6. The display device of claim 3, wherein the fixing cover is positioned between the first back cover and the second back cover.

7. The display device of claim 1, wherein the fixing cover includes a cable passing groove positioned in front of the stand and allowing a cable to pass therethrough.

8. The display device of claim 1, further comprising a stand bracket positioned on a front surface of the fixing cover and fixed to the cover bottom,
wherein the stand assembly includes:
a stand hook caught by the fixing cover; and
a stand screw extending through the fixing cover and fastened to the stand bracket.

9. The display device of claim 8, further comprising:
a module substrate positioned at a lower end of a rear surface of the display device and connected to the display module;
the control module mounted on the first area of the cover bottom; and
a flat cable passing through a space between the stand bracket and the cover bottom to connect the control module with the module substrate.

10. The display device of claim 1, further comprising:
a lower casing top covering a lower portion of a front surface of the display module and a lower end of the display module;
a bottom latch groove defined in the lower casing top; and
a bottom latch formed at a lower edge of the back cover and inserted into the bottom latch groove.

11. The display device of claim 1, further comprising:
a locking groove defined at an outer periphery of the cover bottom; and
an edge protrusion formed at an edge of the back cover and inserted into the locking groove.
